(19) United States
(12) Patent Application Publication
(10) Pub. No.: US 2019/0385879 A1
(43) Pub. Date: Dec. 19, 2019

(54) DELIVERY DEVICE, SUBSTRATE ION-IMPLANTING SYSTEM AND METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Rui Xie, Shenzhen (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 15/577,114

(22) PCT Filed: Sep. 21, 2017
(86) PCT No.: PCT/CN2017/102539

§ 371 Date: Oct. 23, 2018

(30) Foreign Application Priority Data
Jul. 24, 2017 (CN) 201710607786.7

(51) Int. Cl. H01L 21/677; H01J 37/317; H01L 21/265

(52) U.S. Cl. CPC H01L 21/67706; H01L 51/56; H01L 21/26506; H01J 37/3172

(57) ABSTRACT

The present disclosure relates to a delivery device, a substrate ion-implanting system and a substrate ion-implanting method. The substrate ion-implanting system includes: a substrate-supporting table and an ion-implantation device connected to the substrate-supporting table. A substrate is movable from the substrate-supporting table into the ion-implantation device. The ion-implantation device includes an operation chamber, and the substrate is transferred to the operation chamber for implanting ions by the ion-implantation device. A transfer chamber is configured to transfer back the substrate after implanting the ions to the substrate-supporting table. By the above means, the present disclosure can improve the productivity of the substrate ion-implanting system.

The present application is a 35 U.S.C. § 371 National Phase conversion of International (PCT) Patent Application No. PCT/CN2017/102539 filed Sep. 21, 2017, which claims foreign priority to Chinese Patent Application No. 201710607786.7, filed on Jul. 24, 2017 in the State Intellectual Property Office of China, the entire contents of which are hereby incorporated by reference.

### BACKGROUND OF THE INVENTION

### 1. Field of the Invention

The present disclosure relates to the field of manufacturing display panel, and more particularly to a delivery device, a substrate ion-implanting system and a method thereof.

### 2. Discussion of the Related Art

In the manufacturing technology for the OLED (organic light emitting diode), the semiconductor material of the channel layer of the TFT (thin film transistor) primarily includes amorphous silicon (a-Si), microcrystalline silicon (u-Si), low-temperature poly-silicon (LTPS), monocrystalline silicon, organic compound and oxide, etc. The low-temperature poly-silicon (LTPS) technology is a ripest technology of the TFT substrate technology applied in the OLED.

The low-temperature poly-silicon (LTPS) technology applied in the TFT substrate technology is for manufacturing a poly-silicon channel layer. In the technological process thereof, an amorphous silicon layer is deposited on a glass substrate via the ion implantation, and then the amorphous silicon layer is made to absorb energy by the means of laser or non-laser, so as to rearrange atoms thereof to form a poly-silicon structure.

Currently, in the LTPS industry of the OLED, the maximum size of the ion implantation apparatus is a size for the G6 generation glass. With the development of the OLED, the LTPS technology will be applied in the field of the large-size display screen, thus it requires the LTPS technology of the OLED is applied in the glass substrate with the large-size. However, if the current ion-implantation apparatus is applied in the glass substrate with the large size, it will cause a high fragmentation rate, and a low productivity.

### SUMMARY

The present disclosure, is to provide relates to a delivery device, a substrate ion-implanting system and a substrate ion-implanting method, which can improve the productivity of the substrate ion-implanting system.

In one aspect, a delivery device includes:
a first guiding rail, a second guiding rail and a supporting table, wherein the first guiding rail and the second guiding rail are parallel to each other and symmetrically arranged at two opposite sides of the supporting table;
the first guiding rail and the second guiding rail are provided with a first magnetic-pole group, the supporting table is provided with a second magnetic-pole group, the second magnetic-pole group is arranged correspondingly to the first magnetic-pole group, and the supporting table is drivable to move back and forth along an extending direction of the rails by changing magnetic interactions between the first magnetic-pole group and the second magnetic-pole group.

In another aspect, a substrate ion-implanting system includes:
a substrate-supporting table; an ion-implantation device, being connected to the substrate-supporting table and a transfer chamber, wherein a substrate is movable from the substrate-supporting table into the ion-implantation device; the ion-implantation device includes an operation chamber, and the substrate is transferred into the operation chamber for implanting ions via the ion-implantation device; the transfer chamber is configured to transfer back the substrate after implanting the ions to the substrate-supporting table.

In other aspect, a substrate ion-implanting method includes: using the above substrate ion-implanting system for implanting ions, moving the substrate into the ion-implantation device; implanting the ions into the substrate in the ion-implantation device; and transfer back the substrate after implanting the ions to the substrate-supporting table by the transfer chamber.

In view of the above, the substrate ion-implanting system of the present disclosure has no need to erect the substrate when implanting the ions, and includes the transfer chamber, which transfers back the substrate after implanting the ions, thereby reducing the time of occupying the operation chamber and improve the productivity of the substrate ion-implanting system.

### BRIEF DESCRIPTION OF THE DRAWINGS

FIG. 1 is a schematic structural view of a delivery device in accordance with an embodiment of the present disclosure;

FIG. 2 is a schematic side view of the delivery device as shown in FIG. 1;

FIG. 3 is a schematic structural view of an supporting body in accordance with an embodiment of the present disclosure;

FIG. 4 is a schematic structural view of the supporting body in accordance with another embodiment of the present disclosure;

FIG. 5 is a schematic structural view of a substrate ion-implanting system in accordance with an embodiment of the present disclosure;

FIG. 6 is a schematic flow chart of a substrate ion-implanting method in accordance with an embodiment of the present disclosure;

FIG. 7 is a schematic structural view of a substrate ion-implanting system corresponding to the method as shown in FIG. 6.

### DETAILED DESCRIPTION OF THE EMBODIMENTS

Embodiments of the disclosure will now be described more fully hereinafter with reference to the accompanying drawings, in which embodiments of the disclosure are shown.

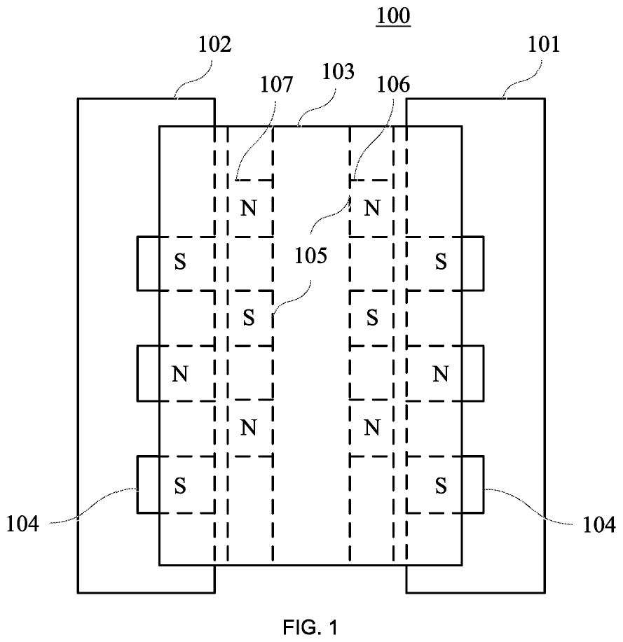

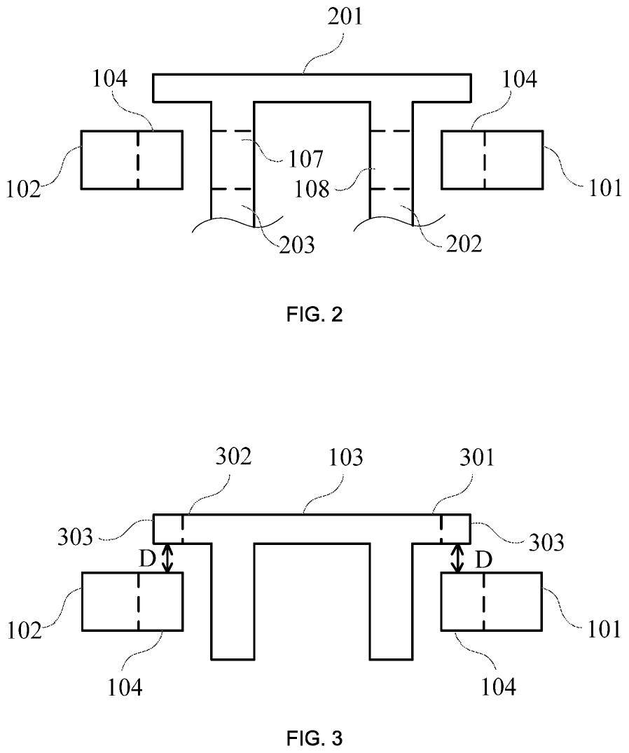

Please refer to FIGS. 1-2, in which FIG. 1 is a schematic structural view of a delivery device in accordance with an embodiment of the present disclosure, and FIG. 2 is a schematic side view of the delivery device as shown in FIG. 1.

In the present embodiment, the delivery device 100 includes a first guiding rail 101, a second guiding rail 102 and a supporting table 103. The first guiding rail 101 and the second guiding rail 102 are parallel with each other and symmetrically arranged at two sides of the supporting table 103. The first guiding rail 101 and the second guiding rail 102 are symmetrically provided with a first magnetic-pole group 104, and the first magnetic-pole group 104 is a group of permanent magnets consisted of N poles and S poles alternately arranged in sequence. As will be understood by those skilled in the art, the first magnetic-pole group 104 is the group of the permanent magnets. That is, the magnetic properties of the N poles and the S poles of the first magnetic-pole group 104 are constant, and the arrangement sequence of the N poles and the S poles of the first magnetic-pole group 104 are constant. The number of the permanent magnets of the first magnetic-pole group 104 is determined by the sizes of the first guiding rail 101 and the second guiding rail 102 and the size of each of the permanent magnets, and is not limited herein.

Optionally, the supporting table 103 includes a top plate 201, a first side plate 202 and a second side plate 203, which are integratedly formed. The top plate 201 is suspended above the first guiding rail 101 and the second guiding rail 102. The first side plate 202 and the second side plate 203 are arranged at a side of the supporting table 103 adjacent to the first guiding rail 101 and the second guiding rail 102, the first side plate 202 is arranged correspondingly to the first guiding rail 101, and the second side plate 203 is arranged correspondingly to the second guiding rail 102. The first side plate 202 and the second side plate 203 are symmetrically provided with a second magnetic-pole group 105, and the second magnetic-pole group 105 includes a first coil group 106 and a second coil group 107. The first side plate 202 is provided with the first coil group 106, which corresponds to the first magnetic-pole group 104 of the first guiding rail 101; and the second side plate 203 is provided with the second coil group 107, which corresponds to the first magnetic-pole group 104 of the second guiding rail 102. The first coil group 106 and the second coil group 107 are electromagnetic induction coil groups respectively. Each coil of the first coil group 106 and the second coil group 107 has a current direction different from adjacent coils thereof, thus the magnetic poles of the first coil group 106 and the second coil group 107 may be changed by changing the current directions of the first coil group 106 and the second coil group 107. The first magnetic-pole group 104 on the first guiding rail 101 and the second guiding rail 102, cooperates with the first coil group 106 and the second coil group 107 having the continuously-changed magnetic poles, to drive the supporting table 103 to move back and forth in an extending direction of the first guiding rail 101 and the second guiding rail 102.

As will be understood by the persons skilled in the art that, two like magnetic poles attract each other, and two opposite magnetic poles repel each other. Thus, the supporting table 103 is drivable to move back and forth in the extending direction of the first guiding rail 101 and the second guiding rail 102, by the cooperation of the first magnetic-pole group 104 on the first guiding rail 101 and the second guiding rail 102, and the first coil group 106 and the second coil group 107 having the continuously-changed magnetic poles. Obviously, the sizes of the coils, the magnitudes of the currents and the rates for changing the current directions of the first coil group 106 and the second coil group 107, are determined by the weight of the supporting table 103, the moving speed of the supporting table 103 and the magnitudes of the magnetic forces of the permanent magnets of the first magnetic-pole group 105, and these are not limited herein.

In the present embodiment, the first magnetic-pole group 104 is a group of permanent magnets, and the second magnetic-pole group 105 is a group of coils with variable magnetic poles. The supporting table 103 is drivable to move by the cooperation of the first magnetic-pole group 104 and the second magnetic-pole group 105. Obviously, as will be understood by those skilled in the art, the first magnetic-pole group may be a group of coils with variable magnetic poles, and the second magnetic-pole group may be a group of permanent magnets, thus the supporting table 103 also may be driven to move by the cooperation method described in the above. Optionally, the first magnetic-pole group and the second magnetic-pole group may be both groups of coils with variable magnetic poles respectively, and it only requires that the rates for changing the magnetic poles thereof are same, and each of the magnetic poles of the first magnetic-pole group has a magnetic polarity opposite to that of an adjacent magnetic pole of the second magnetic-pole group, and they attract each other. These are not limited herein.

Please refer to FIG. 3, and FIG. 3 is a schematic structural view of a supporting body in accordance with an embodiment of the present disclosure.

In the present embodiment, the supporting table 103 further includes a first supporting body 301 and the second supporting body 302. The first supporting body 301 and the second supporting body 302 are provided with a third magnetic-pole group 303, and the third magnetic-pole group 303 is arranged relative to the top of the first magnetic-pole group 104. The third magnetic-pole group 303 is a group of permanent magnets, which are arranged in a same order as that of the permanent magnets of the first magnetic-pole group 104, such that the first magnetic-pole group 104 and the third magnetic-pole group 303 repel each other. As will be understood by those skilled in the art, the repulsive force between the first magnetic-pole group 104 and the third magnetic-pole group 303 is balanced with the gravity of the supporting table 103, such that an interval D between the supporting table 103 and the first guiding rail 101 or the second guiding rail 102 in a vertical direction is controlled. Obviously, the size of the interval D between the supporting table 103 and the first guiding rail 101 or the second guiding rail 102 in the vertical direction, is determined by the requirements of the structure of the delivery device, and it is not limited herein.

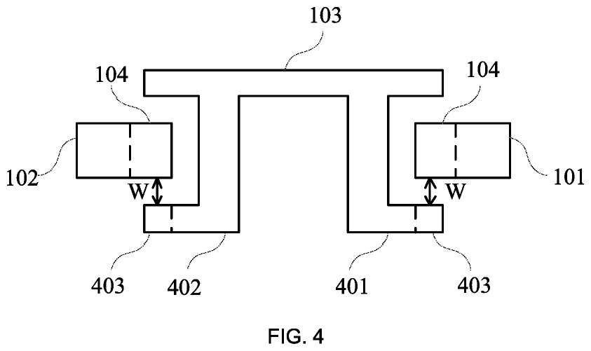

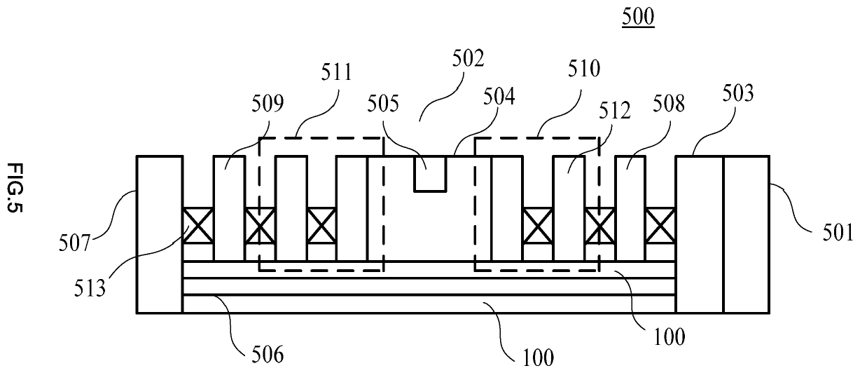

Please refer to FIG. 4, and FIG. 4 is a schematic structural view of a supporting body in accordance with another embodiment of the present disclosure.

In the present embodiment, the supporting table 103 further includes a first supporting body 401 and a second supporting body 402. The first supporting body 401 and the second supporting body 402 are provided with a third magnetic-pole group 403, and the third magnetic-pole group 403 is arranged relative to the bottom of the first magnetic-pole group 104. The third magnetic-pole group 403 is a group of permanent magnets, which are arranged in a order different from that of the permanent magnets of the first magnetic-pole group 104, such that the first magnetic-pole group 104 and the third magnetic-pole group 403 attract each other. As will be understood by those skilled in the art, the attractive force between the first magnetic-pole group 104 and the third magnetic-pole group 403 is balanced with the gravity of the supporting table 103, such that an interval W between the supporting table 103 and the first guiding rail 101 or the second guiding rail 102 in a vertical direction is controlled. Obviously, the size of the interval W between the supporting table 103 and the first guiding rail 101 or the second guiding rail 102 in the vertical direction, is determined by the requirements of the structure of the delivery device, and it is not limited herein.

Please refer to FIG. 5, and FIG. 5 is a schematic structural view of an ion-implanting system in accordance with an embodiment of the present disclosure.

The ion-implanting system 500 includes a substrate-supporting table 501 and an ion-implantation device 502 connected to the substrate-supporting table 501, and the substrate is movable from the substrate-supporting table 501 into the ion-implantation device. The substrate-supporting table 501 is connected to the ion-implantation device 502 via a first handling mechanism 503, and the first handling mechanism 503 is configured to move the substrate from the substrate-supporting table 501 into the ion-implantation device 502. Then, the transfer of the substrate in the ion-implantation device 502 is implemented by the delivery device 100 described in the above embodiments, and the delivery device 100 is arranged at the bottom of the ion-implantation device 502, and the details thereof will not be described again herein.

Optionally, the first handling mechanism 503 may be an automated-operation mechanism, such as a robotic arm, etc., and the present disclosure is not limited in this. As will be understood by those skilled in the art, the first handling mechanism 503 may operate in a manner by clamping the substrate and moving the substrate from a platform to another platform.

In the present embodiment, the ion-implantation device 502 includes an operation chamber 504 configured for implanting the ions into the substrate which enters into the ion-implantation device 502 and is transferred into the operation chamber 504. Compared with the prior art which requires to erect the substrate for the ion implantation, an ion source 505 of the operation chamber 504 of the present embodiment is arranged to face a front of the substrate, so that the substrate can be ion-implanted without handling the substrate, thereby reducing the probability of breaking up the substrate due to the adjustment of the position of the substrate. The ion-implanting technology herein is a commonly-used technical means by those skilled in the art, and will be not described again herein.

The ion-implanting system 500 further includes a transfer chamber 506 configured for transferring back the substrate after implanting the ions to the substrate-supporting table 501. The ion-implantation device 502 and the transfer chamber 506 are connected via a second handling mechanism 507, and the substrate is transferred from the ion-implantation device 502 to the transfer chamber 506 by the second handling mechanism 507, and then is transferred back to the substrate-supporting table 501 through the transfer chamber 506. The substrate-supporting table 501 and the transfer chamber 506 are connected via the first handling mechanism 503, which is configured for moving the substrate transferred back by the transfer chamber 506 to the substrate-supporting table 501. The transfer chamber 506 includes the delivery device 100 described in the above embodiments, the delivery device 100 is arranged at the bottom of the transfer chamber 506 to transfer the substrate, and it will not be described again herein.

Optionally, the second handling mechanism 507 has a structure same to that of the first handling mechanism, and will not be described again herein.

In the present embodiment, the ion-implantation device 502 further includes a first exchange chamber 508, a second exchange chamber 509, a first buffering-chamber group 510 and a second buffering-chamber group 511. The first exchange chamber 508 is disposed at a side of the ion-implantation device 502 adjacent to the first handling mechanism 503, and the second exchange chamber 509 is disposed at another side of the ion-implantation device 502 adjacent to the second handling mechanism 507. The first exchange chamber 508 and the second chamber 509 are both vacuum chambers which are used as exchange mediums for the substrate entering from the atmosphere environment into the vacuum environment.

Each of the first buffering-chamber group 510 and the second buffering-chamber group 511 includes at least two buffering-chamber units 512, respectively. The first buffering-chamber group 510 is disposed between the first exchange chamber 508 and the operation chamber 504, and the second buffering-chamber group 511 is disposed between the second exchange chamber 509 and the operation chamber 504. The buffering-chamber units 512 are vacuum chambers and configured for performing a buffering operation when the substrate is transferred in the ion-implantation device 502, thereby reducing the collisions generated between the substrate and the ion-implantation device 502, and reducing the attrition of the substrate.

Obviously, as will be understood by those skilled in the art, the buffering-chamber units 512 of the first buffering-chamber group 510 and the second buffering-chamber group 511 are determined by the requirements of the process for implanting the ions into the substrate. In the present embodiment, the ion-implanting system 500 is described by taking each of the first buffering-chamber group 510 and the second buffering-chamber group 511 including two buffering-chamber units 512 as an example; however, it is not to limit the number of the buffering-chamber units 512 of the present embodiment. Obviously, in the present embodiment, each of the first buffering-chamber group 510 and the second buffering-chamber group 511 may includes one buffering-chamber unit 512, respectively.

Optionally, the first exchange chamber 508 and the first handling mechanism 503 are connected via a first gate valve 513a, the second exchange chamber 509 and the second handling mechanism 507 are connected via a second gate valve 513b, the first exchange chamber 508 and the first buffering-chamber group 510 are connected via a third gate valve 513c, the second exchange chamber 509 and the second buffering-chamber group 511 are connected via a fourth gate valve 513d, any two adjacent buffering-chamber units 512 of the first buffering-chamber group 510 are connected via a fifth gate valve 513e, and any two adjacent buffering-chamber units 512 of the second buffering-chamber group 511 are connected via a sixth gate valve 513f.

Each of the gate valve 513a to 513f described in the above embodiments, is a separation medium between different chambers and/or stations. When the substrate is to be moved from one chamber or station to another chamber or station, a corresponding gate valve may be opened to pass the substrate. After passing the substrate, the corresponding gate valve may be closed to keep the vacuum degree of each of the different chambers or stations, thereby avoiding the influence for the vacuum environment of each of the chambers or stations, which may influence the process of the substrate.

Optionally, the gate valves 513a to 513f may be just a valve assembly, such as socket gate valve, wedge gate valve, etc., which is convenient to block the space between the different chambers or stations, and is not limited herein.

From the above description, it can be seen that, the ion-implanting system of the present disclosure is provided with the transfer chamber, which transfers back the substrate after implanting the ions, thus it reduces the time required to occupy the operation chamber, and does not require the adjustment of the position of the substrate when implanting the ions, thus it can improve the productivity of the ion-implanting system, and reduce the rate of breaking up the substrate.

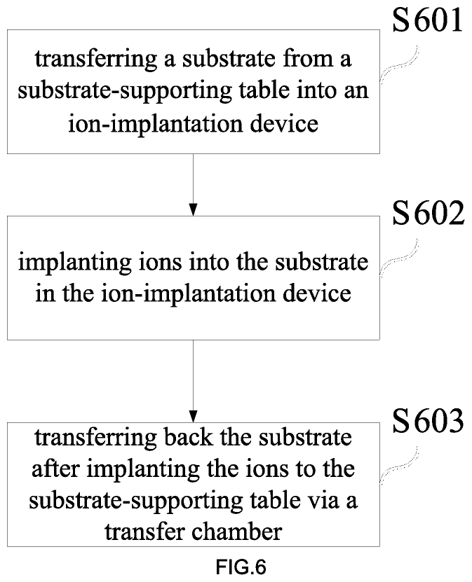

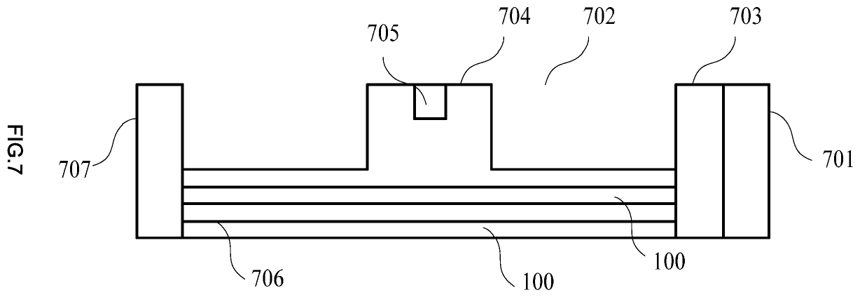

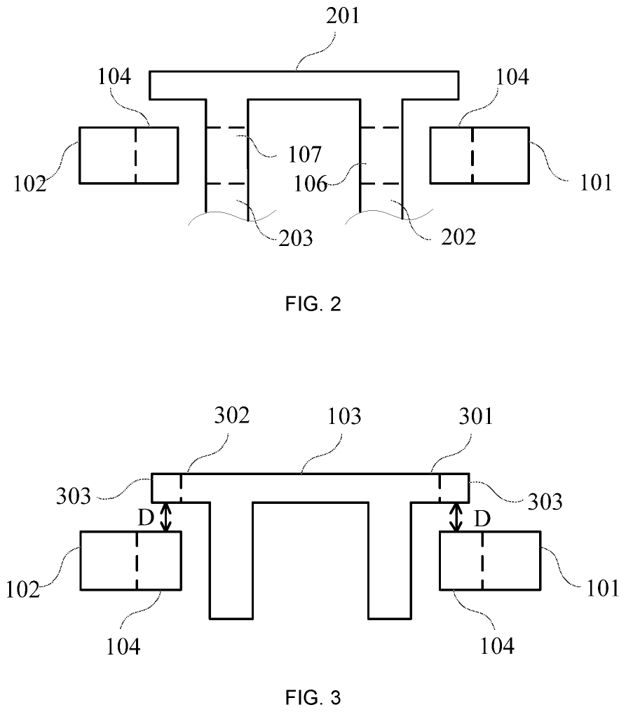

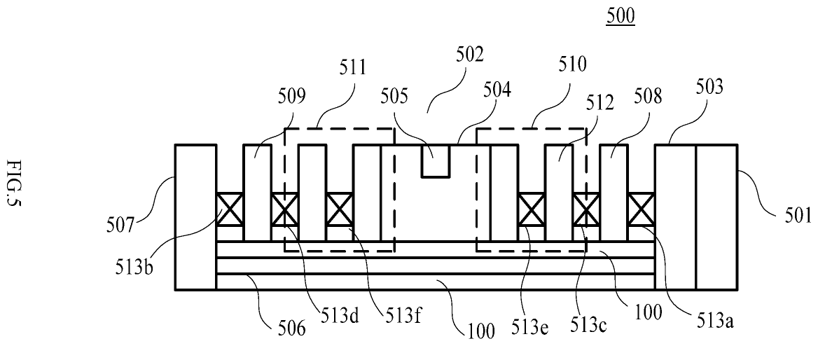

Please refer to FIGS. 6-7, in which FIG. 6 is a schematic flow chart of a substrate ion-implanting method in accordance with an embodiment of the present disclosure, and FIG. 7 is a schematic structural view of a substrate ion-implanting system corresponding to the method as shown in FIG. 6. It should be noted that, the substrate ion-implanting method of the present embodiment is performed by using the substrate ion-implanting system described in the above embodiments. The method includes, but is not limited herein, the following steps:

S601: transferring a substrate from a substrate-supporting table 701 into an ion-implantation device 702;

In the present embodiment, the substrate is transferred from the substrate-supporting table 701 into the ion-implantation device 702 via a first handling mechanism 703, and the specific structure and operation of the first handling mechanism 703 have been described in detail in the above embodiments, and will not be described again herein.

S602: implanting ions into the substrate in the ion-implantation device 702;

In the present embodiment, the substrate in the ion-implantation device 702 is transferred to an operation chamber 704 of the ion-implantation device 702 via the delivery device 100 described in the above embodiments, to be implanted with the ions. As will be understood by those skilled in the art, an ion source 705 of the operation chamber 704 is arranged to face towards a front of the substrate, thus the present embodiment does not require to adjust the position of the substrate to perform the ion implantation, thereby reducing the probability of abrading or breaking up the substrate.

S603: transferring back the substrate after implanting the ions to the substrate-supporting table 701 via a transfer chamber 706;

In the present embodiment, the substrate after implanting the ions is moved to the transfer chamber 706 via a second handling mechanism 707, and the specific structure and operation of the second handling mechanism 707 have been described in detail in the above embodiments, and will not described again herein. The delivery device 100 described in the above embodiments is arranged at the bottom of the transfer chamber 706, such that the transfer chamber 706 transfers back the substrate after implanting the ions to the substrate-supporting table 701 via the delivery device 100.

In summary, the present disclosure employs the transfer chamber, which transfers back the substrate after implanting the ions, to reduce the time required to occupy the operation chamber, and does not require the adjustment of the position of the substrate when implanting the ions, thus it can improve the productivity of the ion-implanting system, and reduce the rate of breaking up the substrate.

What is described above is merely the embodiments of the present disclosure, thus shouldn't be construed to be limiting the patentable scope of the present disclosure. Any equivalent structures or equivalent process flow modifications that are made according to the specification and the attached drawings of the present disclosure, or any direct or indirect applications of the present disclosure in other related technical fields shall all be covered within the scope of the present disclosure.

1. A delivery device, comprising a first guiding rail, a second guiding rail and a supporting table, wherein the first guiding rail and the second guiding rail are parallel to each other and symmetrically arranged at two opposite sides of the supporting table;
wherein the first guiding rail and the second guiding rail are provided with a first magnetic-pole group, the supporting table is provided with a second magnetic-pole group, the second magnetic-pole group is arranged correspondingly to the first magnetic-pole group, and the supporting table is driven to move back and forth along an extending direction of the first guiding rail and the second guiding rail by changing magnetic interactions between the first magnetic-pole group and the second magnetic-pole group.

2. The device as claimed in claim 1, wherein the supporting table further comprises a supporting body provided with a third magnetic-pole group, the third magnetic-pole group is arranged relative to a bottom of the first magnetic-pole group, and the third magnetic-pole group has a magnetic property opposite to that of the first magnetic-pole group, to control an interval between the supporting table and the first guiding rail or the second guiding rail in a vertical direction.

3. A substrate ion-implanting system, comprising:
a substrate-supporting table;
an ion-implantation device, being connected to the substrate-supporting table, wherein a substrate is movable from the substrate-supporting table into the ion-implantation device, the ion-implantation device comprises an operation chamber, and the substrate is transferred into the operation chamber for implanting ions via the ion-implantation device;
a transfer chamber, configured to transfer back the substrate after implanting the ions to the substrate-supporting table.

4. The system as claimed in claim 3, wherein
the substrate-supporting table is connected to the ion-implantation device and the transfer chamber via a first handling mechanism, and the first handling mechanism is configured to move the substrate from the substrate-supporting table into the ion-implantation device, and move the substrate transferred back by the transfer chamber to the substrate-supporting table.

5. The system as claimed in claim 4, wherein
an end of the ion-implantation device away from the substrate-supporting table is connected to an end of the transfer chamber away from the substrate-supporting table via a second handling mechanism, and the second handling mechanism is configured to move the substrate from the ion-implantation device to the transfer chamber, and afterwards the substrate is transferred back to the substrate-supporting table by the transfer chamber.

6. The system as claimed in claim 5, wherein
the ion-implantation device further comprises a first exchange chamber, a second exchange chamber, a first buffering-chamber group, a second buffering-chamber group, the first exchange chamber is arranged at a side of the ion-implantation device adjacent to the first handling mechanism, and the second exchange chamber is arranged at another side of the ion-implantation device adjacent to the second handling mechanism;
each of the first buffering-chamber group and the second buffering-chamber group comprises at least two buffering-chamber units respectively, the first buffering-chamber group is arranged between the first exchange chamber and the operation chamber, and the second buffering-chamber group is arranged between the second exchange chamber and the operation chamber.

7. The system as claimed in claim 6, wherein
the first exchange chamber and the first handling mechanism are connected via a first gate valve, the second exchange chamber and the second handling mechanism are connected via a second gate valve, the first exchange chamber and the first buffering-chamber group are connected via a third gate valve, the second exchange chamber and the second buffering-chamber group are connected via a fourth gate valve, every two adjacent buffering-chamber units of the first buffering-chamber group are connected via a fifth gate valve, and every two adjacent buffering-chamber units of the second buffering-chamber group are connected via a sixth gate valve.

8. The system as claimed in claim 7, wherein the first exchange chamber, the second exchange chamber, each of the buffering-chamber units of the first buffering-chamber group, and each of the buffering-chamber units of the second buffering-chamber group, are vacuum chambers, respectively.

9. The system as claimed in claim 3, wherein each of the ion-implantation device and the transfer chamber comprises a delivery device respectively, the delivery device is arranged at the bottom of the ion-implantation device or the transfer chamber, to transfer the substrate between different chambers or stations.

10. The system as claimed in claim 9, wherein the delivery device comprises a first guiding rail, a second guiding rail and a supporting table, the first guiding rail and the second guiding rail are parallel with each other and symmetrically arranged at two sides of the supporting table;
wherein the first guiding rail and the second guiding rail are provided with a first magnetic-pole group, the supporting table is provided with a second magnetic-pole group, the second magnetic-pole group is arranged correspondingly to the first magnetic-pole group, and the supporting table is driven to move back and forth in an extending direction of the first guiding rail and the second guiding rail by changing magnetic interactions between the first magnetic-pole group and the second magnetic-pole group.

11. The system as claimed in claim 10, wherein the supporting table further comprises a supporting body provided with a third magnetic-pole group, and the third magnetic-pole group is arranged relative to a top or a bottom of the first magnetic-pole group, and the third magnetic-pole group has a magnetic property opposite to that of the first magnetic-pole group, to control an interval between the supporting table and the first guiding rail or the second guiding rail in a vertical direction.

12. A substrate ion-implanting method, using a substrate ion-implanting system to implant ions into a substrate, wherein the substrate ion-implanting system comprises: a substrate-supporting table, an ion-implantation device connected to the substrate-supporting table, and a transfer chamber, the substrate is movable from the substrate-supporting table into the ion-implantation device, the ion-implantation device comprises an operation chamber, the substrate is transferred into the operation chamber for implanting ions via the ion-implantation device, and the transfer chamber is configured to transfer back the substrate after implanting the ions to the substrate-supporting table; and the substrate ion-implanting method comprises:
moving the substrate from the substrate-supporting table into the ion-implantation device;
implanting the ions into the substrate in the ion-implantation device; and
transferring back the substrate after implanting the ions to the substrate-supporting table by the transfer chamber.

13. The device as claimed in claim 1, wherein the supporting table further comprises a supporting body provided with a third magnetic-pole group, the third magnetic-pole group is arranged relative to a top of the first magnetic-pole group, and the third magnetic-pole group has a magnetic property same to that of the first magnetic-pole group, to control an interval between the supporting table and the first guiding rail or the second guiding rail in a vertical direction.

14. The system as claimed in claim 10, wherein the supporting table further comprises a supporting body provided with a third magnetic-pole group, the third magnetic-pole group is arranged relative to a top of the first magnetic-pole group, and the third magnetic-pole group has a magnetic property same to that of the first magnetic-pole group, to control an interval between the supporting table and the first guiding rail or the second guiding rail in a vertical direction.
